(19) United States
(12) Patent Application Publication
(10) Pub. No.: US 2008/0166663 A1
(43) Pub. Date: Jul. 10, 2008

(54) Processing method of light sensitive planographic printing plate material

(75) Inventor: Toshitsugu Suzuki, Tokyo (JP)

Correspondence Address: FRISHAUF, HOLTZ, GOODMAN & CHICK, PC, 220 Fifth Avenue, 16TH Floor, NEW YORK, NY, 10001-7708, US

(73) Assignee: KONICA MINOLTA MEDICAL & GRAPHIC, INC., Tokyo (JP)

(21) Appl. No.: 11/891,525

(22) Filed: Aug. 10, 2007

(30) Foreign Application Priority Data
Aug. 18, 2006 (JP) JP2006-223156

(51) Int. Cl. G03F 7/00

(52) U.S. Cl. 430/309

(57) ABSTRACT

Disclosed is a processing method of a light sensitive planographic printing plate material comprising an aluminum support and provided thereon, a light sensitive layer and an oxygen shielding layer in that order, employing an automatic developing machine comprising a pre-washing section with a pre-washing water, a development section and a post-washing section with a post-washing water, the processing method comprising the steps of imagewise exposing the light sensitive planographic printing plate material, pre-washing the exposed material with the pre-washing water to remove the oxygen shielding layer, developing the pre-washed material with a developer with a pH of from 10 to 12 containing no silicate, and post-washing the developed material with a post-washing water, wherein pre-washing water used for pre-washing is introduced into post-washing water and reused.

This application is based on Japanese Patent Application No. 2006-223156, filed on Aug. 18, 2006 in Japanese Patent Office, the entire content of which is hereby incorporated by reference.

### FIELD OF THE INVENTION

The present invention relates to a processing method of a light sensitive planographic printing plate material, and particular to a processing method of a light sensitive planographic printing plate material comprising a photopolymerizable light sensitive layer containing an ethylenically unsaturated compound, the method minimizing stains or spot-like contaminations at non-image portions even when the method comprises the step of developing the light sensitive planographic printing plate material with a developer containing no silicate, the developing being difficult to obtain sufficient hydrophilicity at non-image portions of a printing plate.

### BACKGROUND OF THE INVENTION

Alkali metal silicate developers have been extensively used to develop a planographic printing plate material. In the light sensitive layer of a conventional planographic printing plate material, ortho-quinonediazide compounds are used in combination with novolak resin and an aqueous alkaline silicate solution capable of dissolving novolak resin is used as a developer. Such a developer has a pH of about 13 to dissolve the novolak resin of the light sensitive layer, and therefore, silicates exhibiting superior pH buffer effect at a pH of around 13 are incorporated in the developer to provide a pH stability of the developer (see for example, Japanese Patent O.P.I. Publication No. 8-160633). However, the pH of a silicate-containing developer lowers due to dissolution of the light sensitive layer during development or absorption of carbon dioxide in air, so that the silicate solidifies and results in sludge. The resulting sludge contaminates a developed planographic printing plate material. Further, a silicate-containing developer is incorporated into a washing water of a washing section where washing is carried out after development, and the silicate solidifies or gels in the washing water to result in sludge, which also contaminates a developed planographic printing plate material. The contaminated planographic printing plate tends to produce dotted stains in printed matter.

A photopolymerizable light sensitive layer containing an ethylenically unsaturated compound of a photopolymer-type printing plate material for CTP does not contain novolak resin, and therefore, such a photopolymer-type printing plate material enables use of a developer with a pH of less than 12.5, which does not require a silicate as a buffering agent, and therefore, enables use of a developer containing no silicate. The developer containing no silicate has advantage in that sludge resulting from solidification of silicates is not produced even when pH of the developer lowers as use of the developer proceeds (see Japanese Patent O.P.I. Publication No. 2002-251019). The silicate is a good hydrophilicity-providing agent. Accordingly, the developer containing no silicate has disadvantage in that it is difficult to obtain sufficient hydrophilicity of an aluminum support surface forming non-image portions of a printing plate obtained after development of a planographic printing plate material, resulting in occurrence of stain. Generally, a light sensitive planographic printing plate material with higher sensitivity can shorten exposure time, and a planographic printing plate can be obtained at a higher speed. When printing is carried out employing such a light sensitive planographic printing plate material, stopped for rest or registration for a while, and then restarted, spot stains at non-image portions (hereinafter also referred to as spot-like contaminations) are likely to occur. In order to prevent such spot-like contaminations, a method has been sought which secures hydrophilicity at non-image portions of the planographic printing plate.

When a planographic printing plate is prepared from a light sensitive planographic printing plate material, a plate protecting solution is coated on the planographic printing plate at a final plate-making step. An object of the coating is not only to maintain hydrophilicity of the non-image portions of the printing plate but also to prevent stains due to fingerprint, oil and fat or dust or scratches on the plate surface, which may be produced while the printing plate is stored for a storage period from the preparation till printing or reuse or the printing plate is handled or mounted on a printing press and to prevent occurrence of stains due to oxidization.

An aqueous solution of gum arabic, cellulose gum, or a water-soluble polymer compound having a carboxyl group in the molecule has been used as a conventional plate protecting solution for planographic printing plate materials. Besides the above, there are proposed a plate protecting solution containing a phosphoric acid-modified starch (see Japanese Patent O.P.I. Publication No. 62-11693), a plate protecting solution containing a carboxyalkyl starch (see Japanese Patent O.P.I. Publication Nos. 62-7595), a plate protecting solution containing a specific polyoxyethylene-containing surfactant (see Japanese Patent O.P.I. Publication No. 11-288196), and many other plate protecting solutions containing a water-soluble polymer. However, simple use of these plate protecting solutions cannot provide a sufficient hydrophilicity of a plate printing plate surface cannot prevent completely occurrence of contaminations, particularly spot-like contaminations.

In recent years, in printing industries, printing ink containing no petroleum volatile organic compound (VOC) has been developed and used in view of environmental protection. As eco friendly printing ink, there are, for example, soybean oil ink “Naturalith 100” produced by Dainippon Ink Kagaku Kogyo Co., Ltd., VOC zero ink “TK HIGH ECO SOY 1” produced by Toyo Ink Manufacturing Co., Ltd., and process ink “Soycelvo” produced by Tokyo Ink Co., Ltd. However, such eco friendly printing ink has problem in that spot-like contaminations occur.

### SUMMARY OF THE INVENTION

The present invention has been made in view of the above. An object of the invention is to provide a processing method of a light sensitive planographic printing plate material comprising a photopolymerizable light sensitive layer containing an ethylenically unsaturated compound, the method minimizing stains or spot-like contaminations at non-image portions even when the method comprises the step of developing the light sensitive planographic printing plate material with a developer containing no silicate, the developing being difficult to obtain sufficient hydrophilicity at non-image portions of a printing plate, and particularly to provide a processing method of the light sensitive planographic printing plate material markedly exhibiting the above advantageous effects when an eco friendly printing ink containing no petroleum volatile organic compound (VOC) is used during printing which has been put into practical use in recent years.

### BRIEF DESCRIPTION OF THE DRAWING

FIG. 1 shows one embodiment of an automatic developing machine used in the invention.

### DETAILED DESCRIPTION OF THE INVENTION

The above object of the invention can be attained by one of the following constitutions.

1. A processing method of a light sensitive planographic printing plate material comprising an aluminum support and provided thereon, a photopolymerizable light sensitive layer and an oxygen shielding layer in that order, employing an automatic developing machine, the photopolymerizable light sensitive layer containing an ethylenically unsaturated compound, a photopolymerization initiator and a polymeric binder, the oxygen shielding layer containing a water soluble polymer and a chelating agent, and the automatic developing machine comprising a pre-washing section with a pre-washing water for removing the oxygen shielding layer, a development section and a post-washing section with a post-washing water, and being structured in such a manner that pre-washing water used in the pre-washing section is introduced into the post-washing section and reused, the processing method comprising the step of (a) imagewise exposing the light sensitive planographic printing plate material, (b) pre-washing the exposed light sensitive planographic printing plate material with the pre-washing water to remove the oxygen shielding layer, (c) developing the pre-washed light sensitive planographic printing plate material with a developer with a pH of from 10 to 12 containing no silicate, and (d) post-washing the developed light sensitive planographic printing plate material with the post-washing water, wherein pre-washing water used for pre-washing is introduced into post-washing water and reused.

2. A processing method of a light sensitive planographic printing plate material comprising an aluminum support and provided thereon, a photopolymerizable light sensitive layer and an oxygen shielding layer in that order, employing an automatic developing machine, the photopolymerizable light sensitive layer containing an ethylenically unsaturated compound, a photopolymerization initiator and a polymeric binder, the oxygen shielding layer containing a water soluble polymer and a chelating agent, and the automatic developing machine comprising a pre-washing section with a pre-washing water for removing the oxygen shielding layer, a development section and a post-washing section with a post-washing water, and being structured in such a manner that pre-washing water used in the pre-washing section is introduced into the post-washing section and reused, the processing method comprising the step of (a) imagewise exposing the light sensitive planographic printing plate material, (b) pre-washing the exposed light sensitive planographic printing plate material with the pre-washing water to remove the oxygen shielding layer, (c) developing the pre-washed light sensitive planographic printing plate material with a developer with a pH of from 10 to 12 containing silicate in an amount less than 0.5% by weight in terms of SiO₂, and (d) post-washing the developed light sensitive planographic printing plate material with the post-washing water, wherein pre-washing water used for pre-washing is introduced into post-washing water and reused. The preferred embodiment of the invention will be explained below, but the invention is not limited thereto.

In a processing method of imagewise exposing a light sensitive planographic printing plate material comprising an aluminum support and provided thereon, a photopolymerizable light sensitive layer containing an ethylenically unsaturated compound, a photopolymerization initiator and a polymeric binder and an oxygen-shielding layer in that order and developing the exposed planographic printing plate material employing an automatic developing machine, the method of the invention is characterized in that (1) the developing machine comprises a pre-washing section for removing the oxygen-shielding layer before development and a post-washing section for post-washing the developed planographic printing plate and being structured in such a manner that pre-washing water in the pre-washing section used for pre-washing is introduced in the post-washing water section and reused, (2) the oxygen shielding layer contains a chelating agent and (3) the developer has a pH of from 10 to 12, and does not substantially contain a silicate or the developer has a pH of from 10 to 12 and contains no silicate.

### Developer (Developer Replenisher)

Developer or developer replenisher in the invention is an alkali solution. As an alkali agent in the alkali solution, there is mentioned an inorganic alkali agent such as sodium secondary phosphate, potassium secondary phosphate, ammonium secondary phosphate, sodium hydrogen carbonate, potassium hydrogen carbonate, ammonium hydrogen carbonate, sodium carbonate, potassium carbonate, ammonium carbonate, sodium borate, potassium borate, lithium borate, sodium hydroxide, potassium hydroxide, or ammonium hydroxide.

The developer or developer replenisher can contain organic alkali agents such as monomethylamine, dimethylamine, trimethylamine, monoethylamine, diethylamine, triethylamine, monoisopropylamine, diisopropylamine, triisopropylamine, n-butylamine, monoethanolamine, diethanolamine, triethanolamine, monoisopropanolamine, diisopropanolamine, ethyleneimine, ethylenediamine, and pyridine.

These alkali agents can be used singly or as a mixture of two or more thereof. The developer or developer replenisher can contain an anionic surfactant, an amphoteric surfactant, or an organic solvent such as alcohol.

In the invention, the developer contains no silicate or does not substantially contain a silicate.

In the invention, “the developer does not substantially contain a silicate” means that the developer contains a silicate in an amount less than 0.5% by weight in terms of SiO₂.

A developer containing a silicate in amount of not less than 0.5% by weight has problems in that the silica solidifies or gels to produce sludge in the developer or the silica is incorporated into the post-washing water and solidifies or gels to produce sludge in the post-washing water, which contaminates a developed planographic printing plate material, and results in dotted stains in printed matter.

The developer in the invention has a pH of from 10 to 12, and preferably from 10.5 to 11.5. A developer having a pH of less than 10 dissolves an alkali soluble resin contained in a light sensitive layer with difficulty, which may result in development failure, while a developer having a pH exceeding 12, which does not contain substantially or at all a silicate as an anti-dissolution agent inhibiting dissolution of the aluminum in the developer, dissolves an aluminum support in the developer during development, which results in an occurrence of sludge.

The invention is characterized in that a developer (hereinafter also referred to as non-silicate developer) containing no silicate which is a strong hydrophilizing agent of an aluminum support, is used in development of the light sensitive planographic printing plate material of the invention comprising a photopolymerizable light sensitive layer containing an ethylenically unsaturated compound.

The non-silicate developer has advantage in that sludge resulting from solidification of silicates is not produced even when pH of the developer lowers by using the developer.

However, the non-silicate developer has disadvantage in that it is difficult to obtain sufficient hydrophilicity of an aluminum support surface forming non-image portions of a printing plate obtained after development of a planographic printing plate material, resulting in occurrence of stain (such as spot-like contamination).

In order to prevent the stain occurrence and maintain hydrophilicity of the non-image portions, the developed planographic printing plate material is ordinarily processed with a finisher.

However, this process alone cannot provide sufficient hydrophilicity of non-image portions and cannot completely prevent occurrence of the spot-like contamination.

The present inventor has made an extensive study. As a result, he has found that when a large number of a planographic printing plate material is processed employing an automatic developing machine, the main cause of the stain occurrence is that calcium and magnesium contained in a post-washing water of the post-washing section of the automatic developing machine is incorporated into a finisher, which lowers its function (maintaining hydrophilicity of non-image portions of a printing plate), and that when a planographic printing plate material comprising an oxygen shielding layer containing a chelating agent is processed employing an automatic developing machine, the oxygen shielding layer is dissolved in a pre-washing water before development to incorporate the chelating agent into a pre-washing water and the resulting pre-washing water is reused in a post-washing water where the calcium and magnesium are sequestered by the chelating agent, so that hydrophilicity of non-image portions of a printing plate is maintained, minimizing occurrence of stain or spot-like contamination at non-image portions.

The present invention will be explained in detail below.

### Oxygen Shielding Layer

In the invention, an oxygen shielding layer is provided on a light sensitive layer described later. The oxygen shielding layer contains a water soluble polymer and a chelating agent. A water soluble polymer capable of forming a layer with a low oxygen permeability is used in the oxygen shielding layer. Typical examples thereof include polyvinyl alcohol and polyvinyl pyrrolidone. Polyvinyl alcohol has the effect of preventing oxygen permeation and polyvinyl pyrrolidone has the effect of increasing adhesion between the oxygen shielding layer and the light sensitive layer.

Besides the above two polymers, the oxygen shielding layer may contain a water soluble polymer such as polysaccharide, polyethylene glycol, gelatin, glue, casein, hydroxyethyl cellulose, carboxymethyl cellulose, methyl cellulose, hydroxyethyl starch, gum arabic, sucrose octacetate, ammonium alginate, sodium alginate, polyvinyl amine, polyethylene oxide, polystyrene sulfonic acid, polyacrylic acid, or a water soluble polyamide.

In the planographic printing plate material in the invention, adhesive strength between the oxygen shielding layer and the light sensitive layer is preferably not less than 35 g/10 mm, more preferably not less than 50 g/10 mm, and still more preferably not less than 75 g/10 mm. Preferred composition of the overcoat layer is disclosed in Japanese Patent O.P.I. Publication No. 10-10742.

The adhesive strength can be determined according to the following method. The adhesive tape with a sufficient adhesive force is applied on the oxygen shielding layer, and then peeled together with the overcoat layer under the applied tape in the normal direction relative to the oxygen shielding layer surface. Force necessary to peel the tape together with the overcoat layer is defined as adhesive strength.

The oxygen shielding layer may further contain a surfactant or a matting agent. The oxygen shielding layer is formed, coating on the photopolymerizable light sensitive layer a coating solution in which the components described above overcoat layer are dissolved in an appropriate coating solvent, and drying. The main solvent of the coating solution is preferably water or an alcohol solvent such as methanol, ethanol, or iso-propanol.

The thickness of the oxygen shielding layer is preferably 0.1 to 5.0 μm, and more preferably 0.5 to 3.0 μm.

### (Chelating Agent)

The chelating agent used in the oxygen shielding layer in the invention is selected from the group consisting of citric acid or its salt, for example, its alkali metal (sodium, potassium) salt or its ammonium salt; polyphosphoric acid or its salt, for example, its alkali metal (sodium, potassium) salt or its ammonium salt; aminopolycarboxylic acids such as ethylenediaminetetraacetic acid, diethylenetriaminepentaacetic acid, ethylenediaminedisuccinic acid, methyliminodiacetic acid, β-alaninediacetic acid, L-glutamine diacetic acid, L-aspartic acid diacetic acid, methylglycine diacetic acid, triethylenetetramine-hexaacetic acid, hydroxyethylethylene-diaminetriacetic acid, nitrilotriacetic acid, 1,2-diaminocyclohexane-tetraacetic acid and 1,3-diamino-2-propanoltetraacetic acid or their salts, for example, their alkali metal (sodium, potassium) salts or their ammonium salts; and phosphonic acids such as aminotri(methylenephosphonic acid), ethylenediaminetetra-(methylenephosphonic acid), diethylenetriamine-penta(methylenephosphonic acid), triethylenetetramine-hexa(methylenephosphonic acid), hydroxyethylethylenediamine-tri(methylenephosphonic acid) and 1-hydroxyethane-1,1-diphosphonic acid or their salts, for example, their alkali metal (sodium, potassium) salts or their ammonium salts. The chelating agent in the invention is preferably citric acid or its salt, and more preferably citric acid or its alkali metal salt. The chelating agent content of the oxygen shielding layer is preferably from 0.01% by weight, and more preferably from 0.05 to 0.3% by weight.

### Photopolymerizable Light Sensitive Layer

The photopolymerizable light sensitive layer (hereinafter also referred to as light sensitive layer) in the invention contains a photopolymerization initiator, a polymerizable ethylenically unsaturated compound and a polymeric binder.

### (Photopolymerization Initiator)

Preferred examples of the photopolymerization initiator include a bromine compound represented by formula (1), a bromine compound represented by formula (1), a titanocene compound, a monoalkyltriaryl borate compound, and iron arene complex.

### Formula (1)

R¹—CBr₂—(C═O)—R²

wherein R¹ represents a hydrogen atom, a bromine atom, an alkyl group, an aryl group, an acyl group, an alkylsulfonyl group, an arylsulfonyl group or a cyano group; and R² represents a monovalent substituent, provided that R¹ and R² may combine with each other to form a ring.

### Formula (2)

CBr₃—(C═O)—X—R³

wherein R³ represents a monovalent substituent; and X represents —O— or —NR⁴— in which R⁴ represents a hydrogen atom or an alkyl group, provided that R³ and R⁴ may combine with each other to form a ring.

As the titanocene compounds, there are those described in Japanese Patent O.P.I. Publication Nos. 63-41483 and 2-291. Preferred examples of titanocene compounds include bis(cyclopentadienyl)-Ti-di-chloride, bis(cyclopentadienyl)-Ti-bis-phenyl, bis(cyclopentadienyl)-Ti-bis-2,3,4,5,6-pentafluorophenyl, bis(cyclopentadienyl)-Ti-bis-2,3,5,6-tetrafluorophenyl, bis(cyclopentadienyl)-Ti-bis-2,4,6-trifluorophenyl, bis(cyclopentadienyl)-Ti-bis-2,6-difluorophenyl, bis(cyclopentadienyl)-Ti-bis-2,4-difluorophenyl, bis(methylcyclopentadienyl)-Ti-bis-2,3,4,5,6-pentafluorophenyl, bis(methylcyclopentadienyl)-Ti-bis-2,3,5,6-tetrafluorophenyl, bis(methylcyclopentadienyl)-Ti-bis-2,6-difluorophenyl (IRUGACURE 784, produced by Ciba Speciality Chemicals Co.), bis(cyclopentadienyl)-bis(2,4,6-trifluoro-3-(pyry-1-yl)phenyl)titanium, and bis(cyclopentadienyl)-bis(2,4,6-trifluoro-3-(2-5-dimethylpyry-1-yl)phenyl)titanium.

As the monoalkyltriaryl borate compounds, there are those described in Japanese Patent O.P.I. Publication Nos. 62-150242 and 62-143044. Preferred examples of the monoalkyl-triaryl borate compounds include tetra-n-butyl ammonium n-butyl-trinaphthalene-1-yl-borate, tetra-n-butyl ammonium n-butyl-triphenyl-borate, tetra-n-butyl ammonium n-butyl-tri-(4-tert-butylphenyl)-borate, tetra-n-butyl ammonium n-hexyl-tri-(3-chloro-4-methylphenyl)-borate, and tetra-n-butyl ammonium n-hexyl-tri-(3-fluorophenyl)-borate.

As the iron-arene complexes, there are those disclosed in Japanese Patent O.P.I. Publication No. 59-219307.

Preferred examples of the iron-arene complex include η-benzene-(η-cyclopentadienyl)iron hexafluorophosphate, η-cumene-(η-cyclopentadienyl)iron hexafluorophosphate, η-fluorene-(η-cyclopentadienyl)iron hexafluorophosphate, η-naphthalene-η-cyclopentadienyl)iron hexafluorophosphate, η-xylene-η-cyclopentadienyl)iron hexafluorophosphate, and η-benzene-η-cyclopentadienyl)iron tetrafluorophosphate.

Another photopolymerization initiator can be used in combination. Examples thereof include carbonyl compounds, organic sulfur compounds, peroxides, redox compounds, azo or diazo compounds, halides and photo-reducing dyes disclosed in J. Kosar, “Light Sensitive Systems”, Paragraph 5, and those disclosed in British Patent No. 1,459,563.

Typical examples of the photopolymerization initiator used in combination include the following compounds:

A benzoin derivative such as benzoin methyl ether, benzoin i-propyl ether, or α,α-dimethoxy-α-phenylacetophenone; a benzophenone derivative such as benzophenone, 2,4-dichlorobenzophenone, o-benzoyl methyl benzoate, or 4,4′-bis(dimethylamino) benzophenone; a thioxanthone derivative such as 2-chlorothioxanthone, 2-i-propylthioxanthone; an anthraquinone derivative such as 2-chloroanthraquinone or 2-methylanthraquinone; an acridone derivative such as N-methylacridone or N-butylacridone; α,α-diethoxyacetophenone; benzil; fluorenone; xanthone; an uranyl compound; a triazine derivative disclosed in Japanese Patent Publication Nos. 59-1281 and 61-9621 and Japanese Patent O.P.I. Publication No. 60-60104; an organic peroxide compound disclosed in Japanese Patent O.P.I. Publication Nos. 59-1504 and 61-243807; a diazonium compound in Japanese Patent Publication Nos. 43-23684, 44-6413, 47-1604 and U.S. Pat. No. 3,567,453; an organic azide compound disclosed in U.S. Pat. Nos. 2,848,328, 2,852,379 and 2,940,853; orthoquinondiazide compounds disclosed in Japanese Patent Publication Nos. 36-22062b, 37-13109, 38-18015 and 45-9610; various onium compounds disclosed in Japanese Patent Publication No. 55-39162, Japanese Patent O.P.I. Publication No. 59-14023 and “Macromolecules”, Volume 10, p. 1307 (1977); azo compounds disclosed in Japanese Patent Publication No. 59-142205; metal arene complexes disclosed in Japanese Patent O.P.I. Publication No. 1-54440, European Patent Nos. 109,851 and 126,712, and “Journal of Imaging Science”, Volume 30, p. 174 (1986); (oxo) sulfonium organoboron complexes disclosed in Japanese Patent O.P.I. Publication Nos. 5-213861 and 5-255347; titanocenes disclosed in Japanese Patent O.P.I. Publication Nos. 59-152396 and 61-151197; transition metal complexes containing a transition metal such as ruthenium disclosed in “Coordination Chemistry Review”, Volume 84, p. 85-277 (1988) and Japanese Patent O.P.I. Publication No. 2-182701; 2,4,5-triarylimidazol dimmer disclosed in Japanese Patent O.P.I. Publication No. 3-209477; carbon tetrabromide; organic halide compounds disclosed in Japanese Patent O.P.I. Publication No. 59-107344.

When a laser is employed as a light source, the light sensitive layer in the invention preferably contains a sensitizing dye. A sensitizing dye having an absorption maximum around a wavelength of light is preferably used.

Examples of the sensitizing dyes, which have sensitivity to the wavelengths of visible to near infrared regions, include cyanines, phthalocyanines, merocyanines, porphyrins, spiro compounds, ferrocenes, fluorenes, fulgides, imidazoles, perylenes, phenazines, phenothiazines, polyenes, azo compounds, diphenylmethanes, triphenylmethanes, polymethine acridines, cumarines, ketocumarines, quinacridones, indigos, styryl dyes, pyrylium dyes, pyrromethene dyes, pyrazolotriazole compounds, benzothiazole compounds, barbituric acid derivatives, thiobarbituric acid derivatives, ketoalcohol borate complexes, xanthene dyes, eosin dyes, and compounds disclosed in European Patent No. 568,993, U.S. Pat. Nos. 4,508,811 and 5,227,227, and Japanese Patent O.P.I. Publication Nos. 2001-125255 and 11-271969.

A typical combination of the above photopolymerization initiator and the sensitizing dye is disclosed in Japanese Patent O.P.I. Publication Nos. 2001-125255 and 11-271969.

The content of the photopolymerization initiator is not specifically limited, but is preferably from 0.1 to 20 parts by weight based on 100 parts by weight of a photopolymerizable monomer described later. The content ratio by mol of the photopolymerization initiator to the sensitizing dye in the light sensitive composition of the invention is preferably from 1:100 to 100:1.

### (Polymerizable Ethylenically Unsaturated Compound)

As the polymerizable ethylenically unsaturated compound (hereinafter also referred to as ethylenically unsaturated compound), there are a known monomer such as a conventional radically polymerizable monomer and a polyfunctional monomer or oligomer having two or more of an ethylenic double bond in the molecule generally used in a conventional ultraviolet curable resin composition. The monomers are not specifically limited. Typical examples thereof include a monofunctional acrylate such as 2-ethylhexyl acrylate, 2-hydroxypropyl acrylate, glycerol acrylate, tetrahydrofurfuryl acrylate, phenoxyethyl acrylate, nonylphenoxyethyl acrylate, tetrahydrofurfuryl-oxyethyl acrylate, tetrahydrofurfuryloxyhexanorideacrylate, an ester of 1,3-dioxane-ε-caprolactone adduct with acrylic acid, or 1,3-dioxolane acrylate; a methacrylate, itaconate, crotonate or maleate alternative of the above acrylate; a bifunctional acrylate such as ethyleneglycol diacrylate, triethyleneglycol diacrylate, pentaerythritol diacrylate, hydroquinone diacrylate, resorcin diacrylate, hexanediol diacrylate, neopentyl glycol diacrylate, tripropylene glycol diacrylate, hydroxypivalic acid neopentyl glycol diacrylate, neopentyl glycol adipate diacrylate, diacrylate of hydroxypivalic acid neopentyl glycol-ε-caprolactone adduct, 2-(2-hydroxy-1,1-dimethylethyl)-5-hydroxymethyl-5-ethyl-1,3-dioxane diacrylate, tricyclodecanedimethylol acrylate, tricyclodecanedimethylol acrylate-ε-caprolactone adduct or 1,6-hexanediol diglycidylether diacrylate; a dimethacrylate, diitaconate, dicrotonate or dimaleate alternative of the above diacrylate; a polyfunctional acrylate such as trimethylolpropane triacrylate, ditrimethylolpropane tetraacrylate, trimethylolethane triacrylate, pentaerythritol triacrylate, pentaerythritol tetraacrylate, dipentaerythritol tetraacrylate, dipentaerythritol pentaacrylate, dipentaerythritol hexacrylate, dipentaerythritol hexacrylate-ε-caprolactone adduct, pyrrogallol triacrylate, propionic acid dipentaerythritol triacrylate, propionic acid dipentaerythritol tetraacrylate or hydroxypivalylaldehyde modified dimethylolpropane triacrylate; a methacrylate, itaconate, crotonate or maleate alternative of the above polyfunctional acrylate.

A prepolymer can be used, and examples of the prepolymer include compounds as described later. The prepolymer with a photopolymerizable property, which is obtained by incorporating acrylic acid or methacrylic in an oligomer with an appropriate molecular weight, can be suitably employed. These prepolymers can be used singly, in combination or as their mixture with the above described monomers and/or oligomers.

Examples of the prepolymer include polyester (meth)acrylate obtained by incorporating (meth)acrylic acid in a polyester of a polybasic acid such as adipic acid, trimellitic acid, maleic acid, phthalic acid, terephthalic acid, hymic acid, malonic acid, succinic acid, glutaric acid, itaconic acid, pyromellitic acid, fumalic acid, pimelic acid, sebatic acid, dodecanic acid or tetrahydrophthalic acid with a polyol such as ethylene glycol, ethylene glycol, diethylene glycol, propylene oxide, 1,4-butane diol, triethylene glycol, tetraethylene glycol, polyethylene glycol, grycerin, trimethylol propane, pentaerythritol, sorbitol, 1,6-hexanediol or 1,2,6-hexanetriol; an epoxyacrylate such as bisphenol A.epichlorhydrin.(meth)acrylic acid or phenol novolak.epichlorhydrin.(meth)acrylic acid obtained by incorporating (meth)acrylic acid in an epoxy resin; an urethaneacrylate such as ethylene glycol.adipic acid.tolylenediisocyanate.2-hydroxyethylacrylate, polyethylene glycol.tolylenediisocyanate-2-hydroxyethylacrylate, hydroxyethylphthalyl methacrylate.xylenediisocyanate, 1,2-polybutadieneglycol.tolylenediisocyanate-2-hydroxyethylacrylate or trimethylolpropane.propylene glycol.tolylenediisocyanate.2-hydroxyethylacrylate, obtained by incorporating (meth)acrylic acid in an urethane resin; a silicone acrylate such as polysiloxane acrylate, or polysiloxane-diisocyanate.2-hydroxyethylacrylate; an alkyd modified acrylate obtained by incorporating a methacroyl group in an oil modified alkyd resin; and a spiran resin acrylate.

The light sensitive layer in the invention may contain a monomer such as a phosphazene monomer, triethylene glycol, an EO modified isocyanuric acid diacrylate, an EO modified isocyanuric acid triacrylate, dimethyloltricyclodecane diacrylate, trimethylolpropane acrylate benzoate, an alkylene glycol acrylate, or a urethane modified acrylate, or an addition polymerizable oligomer or prepolymer having a structural unit derived from the above monomer.

The ethylenic monomer used in combination in the invention is preferably a phosphate compound having at least one (meth)acryloyl group. The phosphate compound is a compound having a (meth)acryloyl group in which at least one hydroxyl group of phosphoric acid is esterified, and the phosphate compound is not limited as long as it has a (meth)acryloyl group.

Besides the above compounds, compounds disclosed in Japanese Patent O.P.I. Publication Nos. 58-212994, 61-6649, 62-46688, 62-48589, 62-173295, 62-187092, 63-67189, and 1-244891, compounds described on pages 286 to 294 of “11290 Chemical Compounds” edited by Kagakukogyo Nipposha, and compounds described on pages 11 to 65 of “UV.EB Koka Handbook (Materials)” edited by Kobunshi Kankokai can be suitably used. Of these compounds, compounds having two or more acryl or methacryl groups in the molecule are preferable, and those having a molecular weight of not more than 10,000, and preferably not more than 5,000 are more preferable.

The light sensitive layer in the invention preferably contains an addition polymerizable ethylenically unsaturated compound having a tertiary amino group in the molecule, which is a tertiary amine monomer. Its molecular structure is not limited, but those are preferred in which a tertiary amine having a hydroxyl group is modified with glycidyl methacrylate, methacrylic chloride, or acrylic chloride. Examples thereof include a polymerizable compound disclosed in Japanese Patent O.P.I. Publication Nos. 1-165613, 1-203413 and 1-197213.

A reaction product of a polyhydric alcohol having a tertiary amino group in the molecule, a diisocyanate and a compound having a hydroxyl group and an addition polymerizable ethylenically double bond in the molecule is preferably used in the invention.

Examples of the polyhydric alcohol having a tertiary amino group in the molecule include triethanolamine, N-methyldiethanolamine, N-ethyldiethanolamine, N-ethyldiethanolamine, N-n-butyldiethanolamine, N-tert-butyldiethanolamine, N,N-di(hydroxyethyl)aniline, N,N,N′, N′-tetra-2-hydroxypropylethylenediamine, p-tolyldiethanolamine, N,N,N′,N′-tetra-2-hydroxyethylethylenediamine, N,N-bis(2-hydroxypropyl)aniline, allyldiethanolamine, 3-dimethylamino-1,2-propane diol, 3-diethylamino-1,2-propane diol, N,N-di(n-propylamino)-2,3-propane diol, N,N-di(iso-propylamino)-2,3-propane diol, and 3-(N-methyl-N-benzylamino)-1,2-propane diol, but the invention is not specifically limited thereto.

Examples of the diisocyanate include butane-1,4-diisocyanate, hexane-1,6-diisocyanate, 2-methylpentane-1,5-diisocyanate, octane-1,8-diisocyanate, 1,3-diisocyanatomethylcyclohexanone, 2,2,4-trimethylhexane-1,6-diisocyanate, isophorone diisocyanate, 1,2-phenylene diisocyanate, 1,3-phenylene diisocyanate, 1,4-phenylene diisocyanate, tolylene-2,4-diisocyanate, tolylene-2,5-diisocyanate, tolylene-2,6-diisocyanate, 1,3-di(isocyanatomethyl)benzene, and 1,3-bis(1-isocyanato-1-methylethyl)benzene, but the invention is not specifically limited thereto.

Examples of the compound having a hydroxyl group and an addition polymerizable ethylenically double bond in the molecule include 2-hydroxyethyl methacrylate (MH-1), 2-hydroxyethyl acrylate (MH-2), 4-hydroxybutyl acrylate (MH-4), 2-hydroxypropylene-1,3-dimethacrylate (MH-7), and 2-hydroxypropylene-1-methacrylate-3-acrylate (MH-8).

The reaction product above can be synthesized according to the same method as a conventional method in which a urethaneacrylate compound is ordinarily synthesized employing an ordinary diol, a diisocyanate and an acrylate having a hydroxyl group.

Examples of the reaction product of a polyhydric alcohol having a tertiary amino group in the molecule, a diisocyanate and a compound having a hydroxyl group and an addition polymerizable ethylenically double bond in the molecule will be listed below.

M-1: A reaction product of triethanolamine (1 mole), hexane-1,6-diisocyanate (3 moles), and 2-hydroxyethyl methacrylate (3 moles)
M-2: A reaction product of triethanolamine (1 mole), isophorone diisocyanate (3 moles), and 2-hydroxyethyl methacrylate (3 moles)
M-3: A reaction product of N-n-butyldiethanolamine (1 mole), 1,3-bis(1-cyanato-1-methylethyl)benzene (2 moles), and 2-hydroxypropylene-1-methacrylate-3-acrylate (2 moles)
M-4: A reaction product of N-n-butyldiethanolamine (1 mole), 1,3-di(cyanatomethyl)benzene (2 moles), and 2-hydroxypropylene-1-methacrylate-3-acrylate (2 moles)
M-5: A reaction product of N-methydiethanolamine (1 mole), tolylene-2,4-diisocyanate (2 moles), and 2-hydroxypropylene-1,3-dimethacrylate (2 moles)

In addition to the above, acrylates or methacrylates disclosed in Japanese Patent O.P.I. Publication Nos. 1-105238 and 2-127404 can be used.

The content of the ethylenically unsaturated compound in the light sensitive layer is preferably from 20 to 80% by weight, and more preferably from 30 to 70% by weight.

### (Polymeric Binder)

The photopolymerizable light sensitive layer of the planographic printing plate material of the invention contains a polymeric binder.

The polymeric binder in the invention is one capable of carrying components contained in the light sensitive layer on a support. As examples thereof, there is a polyacrylate resin, a polyvinylbutyral resin, a polyurethane resin, a polyamide resin, a polyester resin, an epoxy resin, a phenol resin, a polycarbonate resin, a polyvinyl butyral resin, a polyvinyl formal resin, a shellac resin or another natural resin. These resins can be used as an admixture of two or more thereof.

The polymeric binder used in the invention is preferably a vinyl copolymer obtained by copolymerization of an acryl monomer, and more preferably a copolymer containing (a) a carboxyl group-containing monomer unit and (b) an alkyl methacrylate or alkyl acrylate unit as the copolymerization component.

Examples of the carboxyl group-containing monomer include an α,β-unsaturated carboxylic acid, for example, acrylic acid, methacrylic acid, maleic acid, maleic anhydride, itaconic acid, itaconic anhydride or a carboxylic acid such as a half ester of phthalic acid with 2-hydroxymethacrylic acid.

Examples of the alkyl methacrylate or alkyl acrylate include an unsubstituted alkyl ester such as methylmethacrylate, ethylmethacrylate, propylmethacrylate, butylmethacrylate, amylmethacrylate, hexylmethacrylate, heptylmethacrylate, octylmethacrylate, nonylmethacrylate, decylmethacrylate, undecylmethacrylate, dodecylmethacrylate, methylacrylate, ethylacrylate, propylacrylate, butylacrylate, amylacrylate, hexylacrylate, heptylacrylate, octylacrylate, nonylacrylate, decylacrylate, undecylacrylate, or dodecylacrylate; a cyclic alkyl ester such as cyclohexyl methacrylate or cyclohexyl acrylate; and a substituted alkyl ester such as benzyl methacrylate, 2-chloroethyl methacrylate, N,N-dimethylaminoethyl methacrylate, glycidyl methacrylate, benzyl acrylate, 2-chloroethyl acrylate, N,N-dimethylaminoethyl acrylate or glycidyl acrylate.

The polymeric binder in the invention can further contain, as another monomer unit, a monomer unit derived from the monomer described in the following items (1) through (14):

1) A monomer having an aromatic hydroxy group, for example, o-, (p- or m-) hydroxystyrene, or o-, (p- or m-) hydroxyphenylacrylate;

2) A monomer having an aliphatic hydroxy group, for example, 2-hydroxyethyl acrylate, 2-hydroxyethyl methacrylate, N-methylolacrylamide, N-methylolmethacrylamide, 4-hydroxybutyl acrylate, 4-hydroxybutyl methacrylate, 5-hydroxypentyl acrylate, 5-hydroxypentyl methacrylate, 6-hydroxyhexyl acrylate, 6-hydroxyhexyl methacrylate, N-(2-hydroxyethyl)acrylamide, N-(2-hydroxyethyl)methacrylamide, or hydroxyethyl vinyl ether;

3) A monomer having an aminosulfonyl group, for example, m- or p-aminosulfonylphenyl methacrylate, m- or p-aminosulfonylphenyl acrylate, N-(p-aminosulfonylphenyl)methacrylamide, or N-(p-aminosulfonylphenyl)acrylamide;

4) A monomer having a sulfonamido group, for example, N-(p-toluenesulfonyl)acrylamide, or N-(p-toluenesulfonyl)-methacrylamide;

5) An acrylamide or methacrylamide, for example, acrylamide, methacrylamide, N-ethylacrylamide, N-hexylacrylamide, N-cyclohexylacrylamide, N-phenylacrylamide, N-nitrophenylacrylamide, N-ethyl-N-phenylacrylamide, N-4-hydroxyphenylacrylamide, or N-4-hydroxyphenylmethacrylamide;

6) A monomer having a fluorinated alkyl group, for example, trifluoromethyl acrylate, trifluoromethyl methacrylate, tetrafluoropropyl methacrylate, hexafluoropropyl methacrylate, octafluoropentyl acrylate, octafluoropentyl methacrylate, heptadecafluorodecyl methacrylate, heptadecafluorodecyl methacrylate, or N-butyl-N-(2-acryloxyethyl)heptadecafluorooctylsulfonamide;

7) A vinyl ether, for example, ethyl vinyl ether, 2-chloroethyl vinyl ether, propyl vinyl ether, butyl vinyl ether, octyl vinyl ether, or phenyl vinyl ether;

8) A vinyl ester, for example, vinyl acetate, vinyl chroloacetate, vinyl butyrate, or vinyl benzoate;

9) A styrene, for example, styrene, methylstyrene, or chloromethystyrene;

10) A vinyl ketone, for example, methyl vinyl ketone, ethyl vinyl ketone, propyl vinyl ketone, or phenyl vinyl ketone;

11) An olefin, for example, ethylene, propylene, isobutylene, butadiene, or isoprene;

12) N-vinylpyrrolidone, N-vinylcarbazole, or N-vinylpyridine,

13) A monomer having a cyano group, for example, acrylonitrile, methacrylonitrile, 2-pentenenitrile, 2-methyl-3-butene nitrile, 2-cyanoethyl acrylate, or o-, m- or p-cyanostyrene;

14) A monomer having an amino group, for example, N,N-diethylaminoethyl methacrylate, N,N-dimethylaminoethyl acrylate, N,N-dimethylaminoethyl methacrylate, polybutadiene urethane acrylate, N,N-dimethylaminopropyl acrylamide, N,N-dimethylacrylamide, acryloylmorpholine, N-isopropylacrylamide, or N,N-diethylacrylamide.

Further another monomer may be copolymerized with the above monomer.

Further, an unsaturated bond-containing vinyl type copolymer is preferred which is obtained by reacting a carboxyl group contained in the above vinyl copolymer molecule with for example, a compound having a (meth)acryloyl group and an epoxy group. Examples thereof include glycidyl acrylate, glycidyl methacrylate and an epoxy group-containing unsaturated compound disclosed in Japanese Patent O.P.I. Publication No. 11-27196.

The weight average molecular weight of the polymeric binder in the invention is preferably from 10,000 to 200,000, measured according to gel permeation chromatography (GPC), but is not limited to that range.

The polymeric binder content of the light sensitive layer is preferably from 10 to 90% by weight, more preferably from 15 to 70% by weight, and still more preferably from 20 to 50% by weight, in view of sensitivity.

The acid value of the polymeric binder is preferably from 10 to 150, more preferably from 30 to 120, and still more preferably from 50 to 90. The above acid value range is preferred in maintaining balance of polarity of the light sensitive layer, whereby aggregation of pigments in a light sensitive layer coating solution can be prevented.

The dry coating amount of the light sensitive layer is preferably from 0.1 to 5 g/m², and more preferably from 0.5 to 3 g/m².

### Aluminum Support

For the aluminum support in the invention, an aluminum plate is used, and may be a pure aluminum plate or an aluminum alloy plate.

As the aluminum alloy, there can be used various ones including an alloy of aluminum and a metal such as silicon, copper, manganese, magnesium, chromium, zinc, lead, bismuth, nickel, titanium, sodium or iron. The surface of the aluminum support is roughened for water retention.

When an aluminum plate is used for an aluminum support, it is preferable that the aluminum plate is subjected to degreasing treatment for removing rolling oil prior to surface roughening (graining). The degreasing treatments include degreasing treatment employing solvents such as trichlene and thinner, and an emulsion degreasing treatment employing an emulsion such as kerosene or triethanol. It is also possible to use an aqueous alkali solution such as caustic soda for the degreasing treatment. When an aqueous alkali solution such as caustic soda is used for the degreasing treatment, it is possible to remove soils and an oxidized film which can not be removed by the above-mentioned degreasing treatment alone. When an aqueous alkali solution such as caustic soda is used for the degreasing treatment, the resulting support is preferably subjected to desmut treatment in an aqueous solution of an acid such as phosphoric acid, nitric acid, sulfuric acid, chromic acid, or a mixture thereof, since smut is produced on the surface of the support. The surface roughening methods include a mechanical surface roughening method and an electrolytic surface roughening method electrolytically etching the support surface.

Though there is no restriction for the mechanical surface roughening method, a brushing roughening method and a honing roughening method are preferable. Though there is no restriction for the electrolytic surface roughening method, a method, in which the support is electrolytically surface roughened in an acidic electrolytic solution, is preferred.

After the aluminum plate has been electrolytically surface roughened, it is preferably dipped in an acid or an aqueous alkali solution in order to remove aluminum dust, etc. produced in the surface of the support. Examples of the acid include sulfuric acid, persulfuric acid, hydrofluoric acid, phosphoric acid, nitric acid and hydrochloric acid, and examples of the alkali include sodium hydroxide and potassium hydroxide. Among those mentioned above, the aqueous alkali solution is preferably used.

The dissolution amount of aluminum in the aluminum plate surface is preferably 0.5 to 5 g/m². After the aluminum plate has been dipped in the aqueous alkali solution, it is preferable for the support to be dipped in an acid such as phosphoric acid, nitric acid, sulfuric acid and chromic acid, or in a mixed acid thereof, for neutralization.

The mechanical surface roughening and electrolytic surface roughening may be carried out singly, and the mechanical surface roughening followed by the electrolytic surface roughening may be carried out.

After the surface roughening, anodizing treatment may be carried out. There is no restriction in particular for the method of anodizing treatment used in the invention, and known methods can be used. The anodizing treatment forms an anodization film on the aluminum plate surface.

The aluminum plate which has been subjected to anodizing treatment is optionally subjected to sealing treatment. For the sealing treatment, it is possible to use known methods using hot water, boiling water, steam, a sodium silicate solution, an aqueous dichromate solution, a nitrite solution and an ammonium acetate solution.

After the above treatment, the aluminum plate is suitably undercoated with a water soluble resin such as polyvinyl phosphonic acid, a polymer or copolymer having a sulfonic acid in the side chain, or polyacrylic acid; a water soluble metal salt such as zinc borate; a yellow dye; an amine salt; and so on, for hydrophilization treatment. The sol-gel treatment support disclosed in Japanese Patent O.P.I. Publication No. 5-304358, which has a functional group capable of causing addition reaction by radicals as a covalent bond, is suitably used. Thus, an aluminum support is prepared.

### Coating

In the invention, the above-described light sensitive layer coating solution is coated on the aluminum support obtained above according to a conventional coating method, and dried to obtain a light sensitive planographic printing plate material.

Examples of the coating method include an air doctor coating method, a blade coating method, a wire bar coating method, a knife coating method, a dip coating method, a reverse roll coating method, a gravure coating method, a cast coating method, a curtain coating method, and an extrusion coating method.

In the invention, there may further be combined printing plate materials, plate surface-protecting agents, raw materials for developer and automatic developing machines, as described in, for example, JP-A Nos. 11-065129, 11-065126, 2000-206706, 2000-081711, 2002-091014, 2002-091015, 2002-091016, 2002-091917, 2002-174907, 2002-182401, 2002-196506, 2002-196507, 2001-202616, 2002-229187, 2002-202615, 2002-251019, 2002-365813, 2003-029427, 2003-021908, 2003-015318, 2003-035960, 2003-043693, 2003-043701, 2003-043702 and 2003-043703.

### EXAMPLES

Next, the present invention will be explained in the following examples, but the present invention is not limited thereto. In the examples, “parts” represents “parts by weight”, and “%” represents “% by weight”, unless otherwise specified. <<Synthesis of Binder>>

### (Synthesis of Acryl Copolymer 1)

Thirty parts of methacrylic acid, 50 parts of methyl methacrylate, 20 parts of ethyl methacrylate, 500 parts of isopropyl alcohol, and 3 parts of α,α′-azobisisobutyro-nitrile were put in a three neck flask under nitrogen atmosphere, and reacted under nitrogen atmosphere for 6 hours at 80° C. in an oil bath. After that, the reaction mixture was refluxed at a boiling point of isopropyl alcohol for one hour, and 3 parts of triethylammonium chloride and 25 parts of glycidyl methacrylate were further added to the mixture, and reacted for additional 3 hours to obtain acryl copolymer 1. The weight average molecular weight of the acryl copolymer 1 was 35,000, measured according to GPC. The glass transition temperature Tg of the acryl copolymer 1 was 85° C., measured according to DSC (differential thermal analysis). <<Preparation of Support>>

A 0.3 mm thick aluminum plate (material 1050, quality H16) was degreased at 60° C. for one minute in a 5% sodium hydroxide solution, washed with water, immersed at 25° C. for one minute in 10% hydrochloric acid solution to neutralize, and then washed with water. The resulting aluminum plate was electrolytically etched using an alternating current at 25° C. for 60 seconds at a current density of 100 A/dm² in a 0.3 weight % nitric acid solution, desmut at 60° C. for 10 seconds in a 5% sodium hydroxide solution. The desmut aluminum plate was anodized at 25° C. for 1 minute at a current density of 10 A/dm² and at a voltage of 15 V in a 15% sulfuric acid solution, and further subjected to hydrophilization at 75° C. in a 1% polyvinyl phosphonic acid solution. Thus, support was obtained.

The center line average surface roughness (Ra) of the support was 0.65 μm.

### <<Preparation of Planographic Printing Plate Material Sample>>

The following photopolymerizable light sensitive layer coating solution 1 was coated on the resulting support through a wire bar, and dried at 95° C. for 1.5 minutes to give a light sensitive layer having a coating amount of 1.5 g/m². Thus, a photopolymerizable light sensitive layer coated sample was prepared.

(Photopolymerizable light sensitive layer coating solution 1)

| | | |
|---|---|---|
| Ethylenically unsaturated compound M-3 | 25.0 | parts |
| (described previously) | | |
| Ethylenically unsaturated compound | 25.0 | parts |
| (NK ESTER 4G, produced by Shinnakamura Kagaku Co., | | |
| Ltd) | | |
| Polymerization initiator BR-22 | 2.0 | parts |
| Polymerization initiator BR-43 | 2.0 | parts |
| Spectral Sensitizing agent dye D-5 | 1.5 | parts |
| Spectral Sensitizing agent dye D-7 | 1.5 | parts |
| Acryl copolymer 1 | 40 | parts |
| Phthalocyanine pigment | 6.0 | parts |
| (MHI 454 produced by Mikuni Sikisosha) | | |
| 2-t-Butyl-6-(3-t-butyl-2-hydroxy-5- | 0.5 | parts |
| methylbenzyl)-4-methylphenylacrylate | | |
| (Sumirizer GS: produced by Sumitomo 3M Co., Ltd.) | | |
| Fluorine-contained surfactant | 0.5 | parts |
| (F-178K: produced by Dainippon Ink Co., Ltd.) | | |
| Methyl ethyl ketone | 80 | parts |
| Cyclohexanone | 820 | parts |

BR43

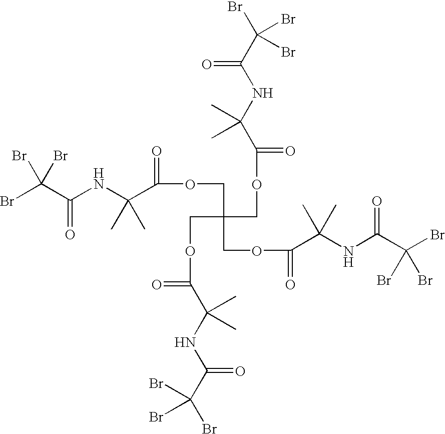

BR22

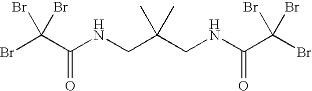

T-1

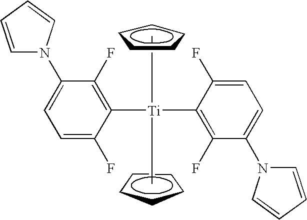

T-2

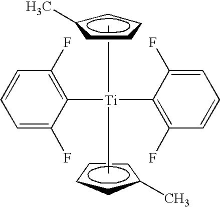

D-5

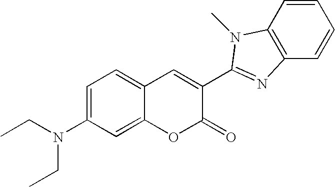

D-7

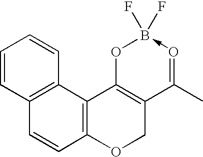

Subsequently, each of the following oxygen shielding layer coating solutions 1, 2 and 3 was coated on the resulting light sensitive layer using an applicator, and dried at 75° C. for 1.5 minutes to give an oxygen shielding layer 1, 2 or 3 with a coating amount of 1.5 g/m². Thus, light sensitive planographic printing plate material samples 1 through 3 with an oxygen shielding layer as shown in Table 1 were prepared.

(Oxygen Shielding Layer Coating Solution 1)

| | | |
|---|---|---|
| Polyvinyl alcohol (GL-05, produced by | 89 | parts |
| Nippon Gosei Kagaku Co., Ltd.) | | |
| Water-soluble polyamide (P-70, produced by | 10 | parts |
| Toray Co. , Ltd. ) | | |
| Surfactant (Surfinol 465, produced by | 0.5 | parts |
| Air Products Inc.) | | |
| Water | 900 | parts |

(Oxygen Shielding Layer Coating Solution 2)

| | | |
|---|---|---|
| Polyvinyl alcohol (GL-05, produced by | 89 | parts |
| Nippon Gosei Kagaku Co., Ltd.) | | |
| Water-soluble polyamide (P-70, produced by | 10 | parts |
| Toray Co., Ltd.) | | |
| Surfactant (Surfinol 465, produced by | 0.5 | parts |
| Air Products Inc.) | | |
| Sodium citrate | 0.05 | parts |
| Water | 900 | parts |

(Oxygen Shielding Layer Coating Solution 3)

| | | |
|---|---|---|
| Polyvinyl alcohol (GL-05, produced by | 89 | parts |
| Nippon Gosei Kagaku Co., Ltd.) | | |
| Water-soluble polyamide (P-70, produced by | 10 | parts |
| Toray Co., Ltd.) | | |
| Surfactant (Surfinol 465, produced by | 0.5 | parts |
| Air Products Inc.) | | |
| Trisodium methylglycin diacetate | 0.05 | parts |
| Water | 900 | parts |

### (Preparation of Planographic Printing Plate Sample)

Employing a plate setter (modification of TigerCat produced by ECRM Co., Ltd.) installed with a 30 mW light source emitting a 408 nm light, light sensitive planographic printing plate material samples 1 through 3 obtained above were imagewise exposed at a resolving degree of 2400 dpi. (Herein, dpi represents the dot numbers per 2.54 cm, and 5 he image pattern used for the exposure comprised a 100% solid image, and a 50% square dot with a screen line number of 175.

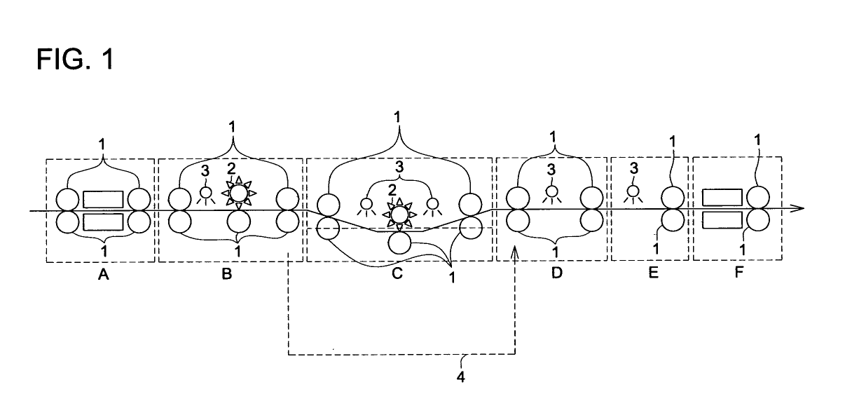

Subsequently, the exposed sample was subjected to development treatment according to processing methods as shown in Table 1, employing an automatic developing machine as shown in FIG. 1 to obtain a planographic printing plate sample. Herein, the automatic developing machine of FIG. 1 comprised a preheating section A set at 105° C., a pre-washing section B for removing an oxygen shielding layer before development of exposed planographic printing plate material, a development section C comprising a developer tank charged with a developer having the developer composition as shown below and a developer replenisher tank charged with a developer replenisher having the composition as shown below, a post-washing section D for removing the developer remaining on developed planographic printing plate material after development, a finishing section E comprising a gum solution tank charged with a gumming solution described below for protecting the surface of the developed material, and a drying section F, wherein a pre-washing water used in the pre-washing section is introduced into the post-washing section through a liquid transporting tube 4. In FIG. 1, numerical number 1 shows a transporting roller, numerical number 2 a brush roller, and numerical number 3 a shower. In the above development, the developer replenisher was introduced in the developer in an amount of 100 ml/m² of planographic printing plate material.

In the processing method Nos. 101 through 105 of Table 1, the pre-washing water used in the pre-washing section was introduced into the post-washing section and reused, while in the processing method No. 106 of Table 1, the pre-washing water used in the pre-washing section was not introduced into the post-washing section.

<Developer 1> (containing no SiO₂)

| | | |
|---|---|---|
| Polyoxyethylene (13) naphthyl ether | 50.0 | g/liter |
| Ethylenediaminetetraacetic acid | 0.5 | g/liter |

| | |
|---|---|
| Potassium hydroxide | Amount giving a pH of 11.8 |
| Water was added to make 1 liter. | |

<Developer Replenisher 1> (containing no SiO₂)

| | | |
|---|---|---|
| Polyoxyethylene (13) naphthyl ether | 50.0 | g/liter |
| Ethylenediaminetetraacetic acid | 0.5 | g/liter |

| | |
|---|---|
| Potassium hydroxide | Amount giving a pH of 12.6 |
| Water was added to make 1 liter. | |

<Developer 2> (containing no SiO₂)

| | | |
|---|---|---|
| Potassium carbonate | 2.5 | g/liter |
| Potassium hydrogen carbonate | 5.0 | g/liter |
| Polyoxyethylene (10) benzyl ether | 50.0 | g/liter |
| Trisodium methylglycin diacetate | 0.5 | g/liter |

| | |
|---|---|
| Potassium hydroxide | Amount giving a pH of 11.4 |
| Water was added to make 1 liter. | |

<Developer Replenisher 2> (containing no SiO₂)

| | | |
|---|---|---|
| Potassium carbonate | 2.5 | g/liter |
| Potassium hydrogen carbonate | 5.0 | g/liter |
| Polyoxyethylene (10) benzyl ether | 50.0 | g/liter |
| Trisodium methylglycin diacetate | 0.5 | g/liter |

| | |
|---|---|
| Potassium hydroxide | Amount giving a pH of 12.2 |
| Water was added to make 1 liter. | |

| | |
|---|---|
| <Developer 3> (containing no SiO₂) | |
| Polyoxyethylene (13) naphthyl ether | 40.0 g/liter |
| sulfonic acid sodium salt (described later) | |
| Trisodium ethylenediaminedisuccinate | 0.5 g/liter |
| Potassium hydroxide | Amount giving a pH of 11.8 |
| Water was added to make 1 liter. | |
| <Developer Replenisher 3> (containing no SiO₂) | |
| Polyoxyethylene (13) naphthyl ether | 40.0 g/liter |
| sulfonic acid sodium salt (having the chemical structure as | |
| shown below) | |
| Ethylenediaminedisuccinic acid | 0.5 g/liter |
| trisodium salt | |
| Potassium hydroxide | Amount giving a pH of 12.6 |
| Water was added to make 1 liter. | |

Polyoxyethylene (13) naphthyl ether sulfonic acid sodium salt

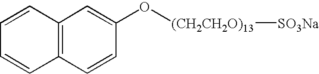

<Developer 4>

| | | |
|---|---|---|
| Aqueous potassium silicate solution | 40.0 | g/liter |
| (Containing 26% by weight of SiO₂ | | |
| and 13.5% by weight of K₂O) | | |
| Ethylenediaminetetraacetic acid | 0.5 | g/liter |
| Sodium butylnaphthalene sulfonate | 20.0 | g/liter |

| | |
|---|---|
| Potassium hydroxide | Amount giving a pH of 12.3 |
| Water was added to make 1 liter. | |

<Developer Replenisher 4>

| | | |
|---|---|---|
| Aqueous potassium silicate solution | 40.0 | g/liter |
| (Containing 26% by weight of SiO₂ | | |
| and 13.5% by weight of K₂O) | | |
| Ethylenediaminetetraacetic acid | 0.5 | g/liter |
| Sodium butylnaphthalene sulfonate | 20.0 | g/liter |

| | |
|---|---|
| Potassium hydroxide | Amount giving a pH of 12.7 |
| Water was added to make 1 liter. | |

<Gumming solution (Finisher)>

| | | |
|---|---|---|
| White dextrin | 5.0% | by weight |
| Hydroxypropyl starch | 10.0% | by weight |
| Gum arabic | 1.0% | by weight |
| Ammonium phosphate | 0.1% | by weight |
| Sodium dilaurylsuccinate | 0.15% | by weight |
| Polyoxyethylene naphthyl ether | 0.5% | by weight |
| Polyoxyethylene-polyoxypropylene | 0.3% | by weight |
| block copolymer (polyoxyethylene | | |
| content of 50 mol %, molecular | | |
| weight of 5000) | | |
| Ethylene glycol | 1.0% | by weight |
| Ethylenediaminetetraacetatic acid | 0.005% | by weight |
| Disodium salt | | |
| 1,2-Benzoisothiazoline-3-on | 0.005% | by weight |
| Water was added to make 1 liter. | | |

### <<Evaluation Method>>

### (Stains at Non-Image Portions)

After 100 m² of light sensitive planographic printing plate sample was subjected to development employing the automatic developing machine, a light sensitive planographic printing plate sample was developed with the fatigued developer to obtain a printing plate sample for evaluation. Employing the resulting printing plate sample, printing was carried out employing a press (DAIYA 1F-1 produced by Mitsubishi Jukogyo Co., Ltd.), wherein coated paper, dampening water (SG-51, H solution produced by Tokyo Ink Co., Ltd., Concentration: 1.5%) and printing ink (Process ink, “SOY CERVO” produced by Tokyo Ink Co., Ltd.,) were used. After 50 sheets were printed, printing was stopped and the number per 100 cm² of stains at non-image portions of the 50^{th} print was counted. The number not more than 1 is acceptable, but the number of not less than 2 is practically problematic. (Spot-like Contaminations at Non-image Portions due to Machine Stop)

After 500 m² of light sensitive planographic printing plate sample was subjected to development to fatigue a developer, employing the automatic developing machine, a light sensitive planographic printing plate sample was developed with the fatigued developer to obtain a printing plate sample for evaluation. Employing the resulting printing plate sample, printing was carried out employing a press (DAIYA 1F-1 produced by Mitsubishi Jukogyo Co., Ltd.), wherein coated paper, dampening water (SG-51, H solution produced by Tokyo Ink Co., Ltd., Concentration: 1.5%) and printing ink (Process ink, “SOY CERVO” produced by Tokyo Ink Co., Ltd.,) were used. After 5000 sheets were printed, printing was stopped for one hour and then printing was restarted and additional 100 sheets were printed. The number per 100 cm² of spot-like contaminations at non-image portions in the 100^{th} print was counted. The number not more than 10 is acceptable, but the number exceeding 10 is practically problematic.

The results are shown in Table 1.

TABLE 1

| Processing | | | | | | | |
|---|---|---|---|---|---|---|---|
| method (No.) | Light | | | | | | |
| of Light | Sensitive | | | | | Evaluation Results | |
| Sensitive | plano-graphic | | Development | | | Stain | Spot-like |
| Plano-graphic | printing Plate | Oxygen | | Developer | Washing | Occurrence | Contaminations |
| Printing Plate | Material | Shielding | Developer | Replenisher | after | at non-image | at non-image |
| Material | No. | Layer No. | No. | No. | Development | portions | portions |
| 101 (Comp.) | 1 | 1 | 1 | 1 | *a | 3 | 25 |
| 102 (Inv.) | 2 | 2 | 2 | 2 | a | 0 | 7 |
| 103 (Inv.) | 3 | 3 | 3 | 3 | a | 0 | 9 |
| 104 (Comp.) | 2 | 2 | 4 | 4 | a | 2 | 5 |
| 105 (Inv.) | 2 | 2 | 1 | 1 | a | 0 | 7 |
| 106 (Comp.) | 2 | 2 | 3 | 3 | **b | 3 | 26 |

Comp.: Comparative, Inv.: Inventive
In Table 1, oxygen shielding layer No. 1 did not contain a chelating agent, and oxygen shielding layer Nos. 2 and 3 contained a chelating agent. None of developer Nos. 1, 2 and 3 and developer replenisher Nos. 1, 2 and 3 contained a silicate, but developer No. 4 and developer replenisher No. 4 contained a silicate. The symbol “a” shows that pre-washing water used before development was introduced in post-washing water used after development and reused there, and the symbol “b” shows that pre-washing water used before development was not introduced in post-washing water used after development and therefore, not reused there.

As is apparent from Table 1 above, the processing method of the invention of a light sensitive planographic printing plate material is excellent in minimizing stains or spot-like contaminations at non-image portions.

The present invention provides a processing method of a light sensitive planographic printing plate material comprising a photopolymerizable light sensitive layer containing an ethylenically unsaturated compound, the method minimizing stains or spot-like contaminations at non-image portions even when the method comprises the step of developing the light sensitive planographic printing plate material with a developer containing no silicate, the developing being difficult to obtain sufficient hydrophilicity at non-image portions of a printing plate, and particularly provides a processing method of the light sensitive planographic printing plate material markedly exhibiting the above advantageous effects when an eco friendly printing ink containing no petroleum volatile organic compound (VOC) is used during printing which has been put into practical use in recent years.

What is claimed is:

1. A processing method of a light sensitive planographic printing plate material comprising an aluminum support and provided thereon, a photopolymerizable light sensitive layer and an oxygen shielding layer in that order, employing an automatic developing machine, the photopolymerizable light sensitive layer containing an ethylenically unsaturated compound, a photopolymerization initiator and a polymeric binder, the oxygen shielding layer containing a water soluble polymer and a chelating agent, and the automatic developing machine comprising a pre-washing section with a pre-washing water for removing the oxygen shielding layer, a development section and a post-washing section with a post-washing water, and being structured in such a manner that pre-washing water used in the pre-washing section is introduced into the post-washing section and reused, the processing method comprising the steps of:
(a) imagewise exposing the light sensitive planographic printing plate material;
(b) pre-washing the exposed light sensitive planographic printing plate material with the pre-washing water to remove the oxygen shielding layer;
(c) developing the pre-washed light sensitive planographic printing plate material with a developer with a pH of from 10 to 12 containing no silicate; and
(d) post-washing the developed light sensitive planographic printing plate material with the post-washing water, wherein pre-washing water used for pre-washing is introduced into post-washing water and reused.

2. The processing method of claim 1, wherein the water soluble polymer in the oxygen shielding layer is polyvinyl alcohol or polyvinyl pyrrolidone.

3. The processing method of claim 1, wherein the chelating agent in the oxygen shielding layer is selected from the group consisting of citric acid or its salt, polyphosphoric acid or its salt, aminopolycarboxylic acids or their salts and phosphonic acids or their salts.

4. The processing method of claim 3, wherein the chelating agent is citric acid or its salt.

5. The processing method of claim 1, wherein the thickness of the oxygen shielding layer is 0.1 to 5.0 am.

6. A processing method of a light sensitive planographic printing plate material comprising an aluminum support and provided thereon, a photopolymerizable light sensitive layer and an oxygen shielding layer in that order, employing an automatic developing machine, the photopolymerizable light sensitive layer containing an ethylenically unsaturated compound, a photopolymerization initiator and a polymeric binder, the oxygen shielding layer containing a chelating agent, and the automatic developing machine comprising a pre-washing section with a pre-washing water for removing the oxygen shielding layer, a development section and a post-washing section with a post-washing water, and being structured in such a manner that pre-washing water used in the pre-washing section is introduced into the post-washing section and reused, the processing method comprising the steps of:
(a) imagewise exposing the light sensitive planographic printing plate material;
(b) pre-washing the exposed light sensitive planographic printing plate material with the pre-washing water to remove the oxygen shielding layer;
(c) developing the pre-washed light sensitive planographic printing plate material with a developer with a pH of from 10 to 12 which contains a silicate in an amount less than 0.5% by weight in terms of SiO₂; and
(d) post-washing the developed light sensitive planographic printing plate material with the post-washing water, wherein pre-washing water used for pre-washing is introduced into post-washing water and reused.

7. The processing method of claim 6, wherein the water soluble polymer in the oxygen shielding layer is polyvinyl alcohol or polyvinyl pyrrolidone.

8. The processing method of claim 6, wherein the chelating agent in the oxygen shielding layer is selected from the group consisting of citric acid or its salt, polyphosphoric acid or its salt, aminopolycarboxylic acids or their salts and phosphonic acids or their salts.

9. The processing method of claim 8, wherein the chelating agent is citric acid or its salt.

10. The processing method of claim 6, wherein the thickness of the oxygen shielding layer is 0.1 to 5.0 μm.
